(19) United States
(12) Patent Application Publication
(10) Pub. No.: US 2006/0066152 A1
(43) Pub. Date: Mar. 30, 2006

(54) Pump connection wiring device

(76) Inventors: Robert G. Klabunde, (US); Curt W. Gederberg, (US)

Correspondence Address: Robert G. Klabunde, P.O. Box 827, Hawley, MN, 56549, US

(21) Appl. No.: 11/237,172

(22) Filed: Sep. 27, 2005

Related U.S. Application Data
(60) Provisional application No. 60/613,178, filed on Sep. 27, 2004.

(51) Int. Cl. H05K 7/14

(52) U.S. Cl. 307/149

(57) ABSTRACT

A pump system wiring device is provided that includes a means for having two separate wiring compartments. The device includes a first wiring compartment for simple plug type connections and a second compartment for hard wire electrical connections. In one embodiment the wiring device further includes a removable cover on the first wiring compartment without the use of special tools. In one embodiment the wiring device provides a double seal arrangement to prevent harmful corrosive septic gases from entering second electrical wiring compartment. A method for implementation of the pump system wiring device is also provided.

### CROSS-REFERENCE TO RELATED APPLICATION

PPA No. 60/613,178

### BACKGROUND OF THE INVENTION

The present invention relates to a system for wiring a pump and alarm circuit in a septic system application. More particularly it relates to a device that separates the electricians wiring from general access electrical connections that a non qualified person can access without exposing the person from dangerous high voltage wiring connections. This device also creates a double seal to protect the electrical connections from harmful septic gases.

Typical septic systems have a pump, pump float switch and alarm float switch that needs to be electrically terminated within an electrical box that meets electrical code requirements. In common with all installations are methods for sealing the electrical box from harmful septic gases, providing means for a pump disconnect and a means for easy access to the pump and pump switch.

One type of installation is to bring the electrical power, pump power cord, and float switches into a single electrical control enclosure. A mixture of “hard” wire connections are made along with simple cord “plug” connections. For instance, electrical power is wired by an electrician to a receptacle. A pump float switch that has a piggy back plug can then be simply “plugged” into the receptacle and at the same time a pump is “plugged” into the piggy back float switch. With this type of installation a non qualified person would have to open the electrical control enclosure and be exposed to the high voltage wiring if an inspection of the pump and pump float were to be made. This type of installation also requires a separate pump disconnecting means to meet electrical code requirements.

It is also common for plumbers or excavators that install the septic systems to install a pump, pump float, and alarm float within the septic tank and then bring the wires up to the area where the electrical control box will be installed by the electrician. By code, a plumber cannot perform “electrical” wiring so coordination needs to be scheduled between the plumber and electrician to complete the installation in the shortest time as possible.

There remains a need in the art for an effective wiring device that makes for installing a pump wiring device in a septic system application in the quickest and safest manner.

### BRIEF SUMMARY OF THE INVENTION

The present invention is a septic system wiring device that separates an electricians “hard” wiring electrical connections independently from the “plug” connections made by a plumber. The septic system wiring device contains two independent wiring enclosures. One enclosure is for the plumber and the other for the electrician. The device allows for the plumber/excavator who installs the septic system to mount the wiring device and make the “plug” connections between a receptacle, pump plug and pump float piggy back plugs in a wiring enclosure that is independent and isolated form the electrical “hard” wiring enclosure. Because the wiring enclosures are separate, the plumber can perform their work independent of the electrician's work and vice versa. This eliminates each party from waiting until the other party has completed work before the job can be completed.

The plumber's enclosure utilizes a cap that is removed without the special use of tools such as a screwdriver. This feature allows the pump to be disconnected by removing the cap and unplugging the pump from the pump float plug and receptacle which complies with the electrical code for providing a “readily accessible disconnecting means for the pump motor.”

The present invention provides for a double seal for protecting the electrical connections from harmful septic gases.

While several alternative embodiments are disclosed, still other embodiments of the present invention will become apparent to those skilled in the art from the following detailed description, wherein is shown and described only the embodiments of the invention, by way of illustration, of the best modes contemplated for carrying out the invention. As will be realized, the invention is capable of modification in various obvious aspects, all without departing from the spirit and scope of the present invention. Accordingly, the drawings and detailed description are to be regarded as illustrative in nature and not restrictive.

### BRIEF DESCRIPTION OF THE DRAWINGS

FIG. 1 is a perspective view of the wiring device showing the components needed for wiring connections.

FIG. 2 is a perspective showing the wiring device connected to a septic tank.

FIG. 3 is a perspective showing the electricians wiring enclosure.

FIG. 4 is an exploded view of the electricians wiring enclosure.

### DETAILED DESCRIPTION

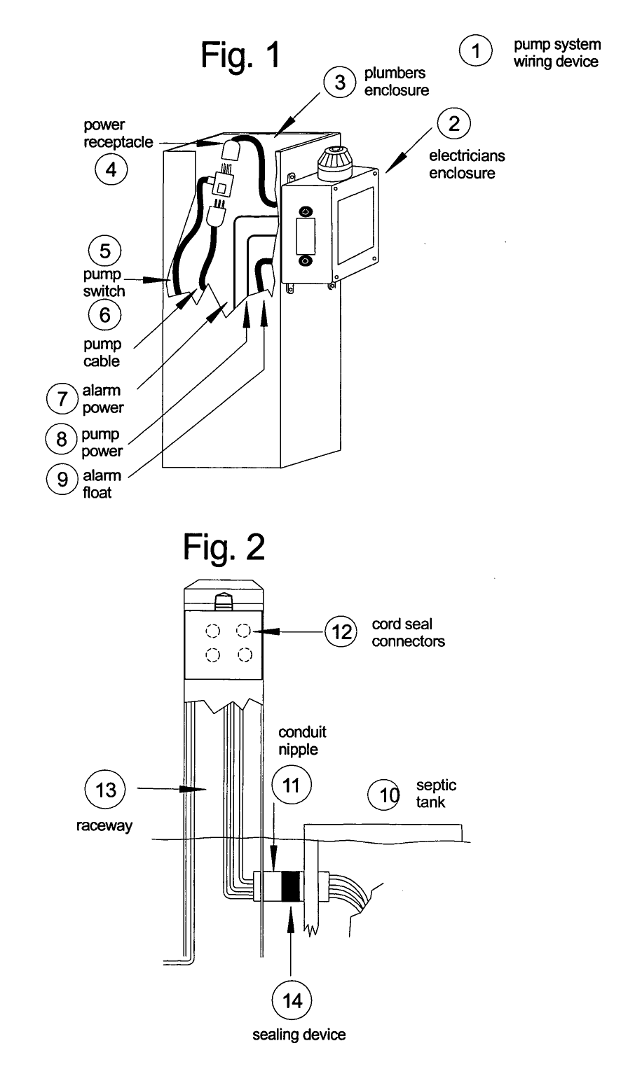

Referring to FIG. 1 and FIG. 2, A pump system wiring device 1 consists of plumbers enclosure 3 and an electricians enclosure 2. The enclosures are coupled together with multiple cord seal connectors 12 which are liquid and gas tight. Both enclosures are preferably made of plastic which is non corrosive to septic gases.

From septic tank 10, the plumber will pull the pump cable 6; pump float switch 5 and alarm float 9 through a conduit nipple 11 and into the plumber's enclosure 3. A sealing device 14 is inserted into conduit nipple 11 to prevent harmful septic gases from entering raceway 13 and plumber's enclosure 3. At this point, the plumber is done and can either make the plug connections or leave for connection at a later time.

The electrician will route the alarm power 7 and pump power 8 cables from the bottom of the pump system wiring device 1 and up into raceway 13 and enter the electrician's enclosure 2 through cord seal connectors 12.

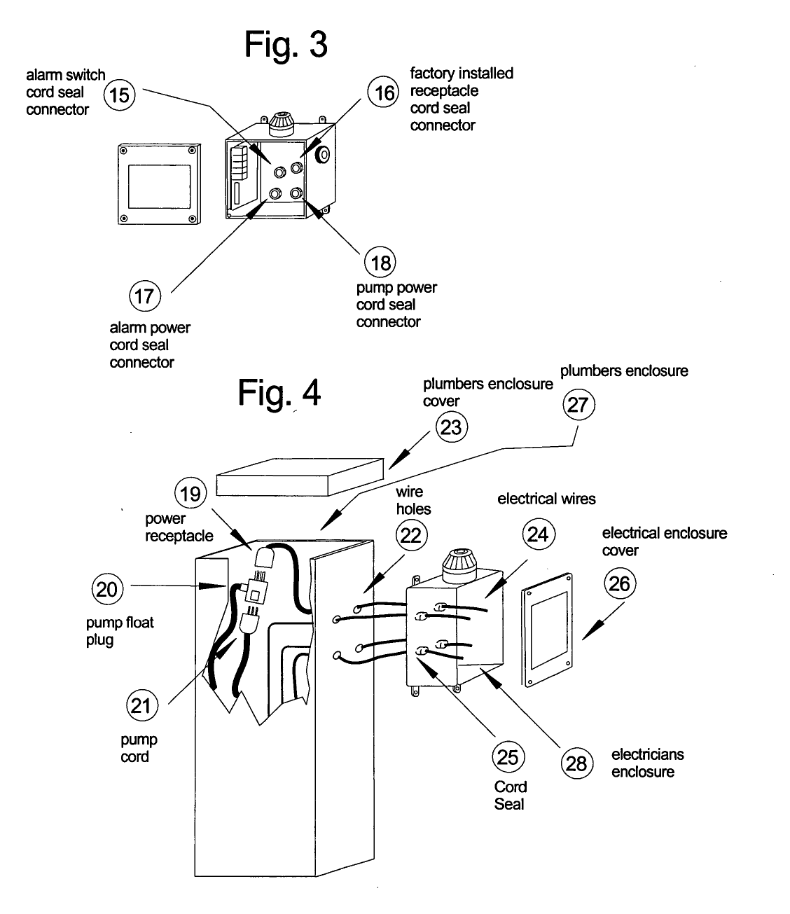

Referring to FIG. 3 and FIG. 4, the electrician will bring electrical wires 24 through wire holes 22 into the electricians enclosure 28. The alarm switch is routed into the electrician's enclosure 28 through cord seal connector 15. Cord seal connector 15 can be tightened to make a liquid and gas tight connection. The electrician routes the alarm power through cord seal connector 17 and pump power through cord seal connector 18. Within the electrician's enclosure 28, the electrician will connect the alarm and pump circuits. The electrical enclosure cover 26 is secured to the electrician's enclosure 28 with four screws making the wiring connections secure and separate from the plumber's enclosure. Since the conduit nipple 11 (from FIG. 2) is equipped from a sealing device 14 (from FIG. 2) and cord seal connectors 15,16,17 and 18 are used, a double seal exists to protect the wiring connections within electricians enclosure 28 from harmful corrosive septic gases.

The pump can be readily disconnected from power by removing plumber's enclosure cover 23 and unplugging the pump cord 21 from power receptacle 19. Also, the pump float can be inspected by removing pump float plug 20 from power receptacle 19 and pump cord 21.

Although the present invention has been described with reference to preferred embodiments, persons skilled in the art will recognize that changes may be made in form and detail without departing from the spirit and scope of the invention.

I/we claim:

1. A system for wiring a pump/alarm system comprising:
A square elongated first wiring area with removable cap at one end; and a second wiring area coupled to first wiring area.

2. The system of claim 1 where the first wiring area is coupled to second wiring area with cord seal connectors.

3. The system of claim 1 where the first wiring area has a removable cap without the use of special tools.

4. The system of claim 1 with a first sealing device to prevent gases from entering first wiring area and a second sealing means between first wiring area and second wiring area.
